(19) United States
(12) Patent Application Publication
(10) Pub. No.: US 2025/0237829 A1
(43) Pub. Date: Jul. 24, 2025

(54) OPTOELECTRONIC COMPONENT

(71) Applicant: ams-OSRAM International GmbH, Regensburg (DE)

(72) Inventors: Martin HETZL, Painten (DE); Horst VARGA, Lappersdorf (DE); Dirk BECKER, Langquaid (DE); Tansen VARGHESE, Regensburg (DE); Norwin von Malm, Nittendorf (DE)

(73) Assignee: ams-OSRAM International GmbH, Regensburg (DE)

(21) Appl. No.: 18/700,729

(22) PCT Filed: Aug. 12, 2022
(86) PCT No.: PCT/EP2022/072662

§ 371 Date: Apr. 12, 2024

(30) Foreign Application Priority Data
Oct. 15, 2021 (DE) 102021126783.8

(51) Int. Cl. G02B 6/43; G02B 6/42

(52) U.S. Cl. CPC G02B 6/43; G02B 6/4249

(57) ABSTRACT

The invention relates to an optoelectronic component, including the following features: an emitter, which is operated with an electrical input voltage and generates electromagnetic radiation during operation, a plurality of receivers, which form a receiver array, wherein the receiver array converts electromagnetic radiation emitted from the emitter during operation into an electrical output voltage, wherein radiation coupling-in surfaces of the receivers are located on a radiation coupling-out surface of the emitter, and a radiation-influencing element is disposed between the emitter and the receiver array, wherein the radiation-influencing element guides electromagnetic radiation generated by the emitter onto radiation coupling-out surfaces of the receivers.

### CROSS-REFERENCE TO RELATED APPLICATIONS

The present application is a national stage entry from International Application No. PCT/EP2022/072662, filed on Aug. 12, 2022, published as International Publication No. WO 2023/061638 A1 on Apr. 20, 2023, and claims priority to German Patent Application No. 10 2021 126 783.8, filed Oct. 15, 2021, the disclosures of all of which are hereby incorporated by reference in their entireties.

### FIELD

An optoelectronic component is specified.

### BACKGROUND

An improved optoelectronic component is to be specified which is configured for electrical voltage conversion and, in particular, can be designed to be as compact as possible. This object is solved by an optoelectronic component with the features of claim 1.

Advantageous embodiments and further developments of the optoelectronic component are specified in the dependent claims.

### SUMMARY

According to an embodiment, the optoelectronic component comprises an emitter that is operated with an electrical input voltage and generates electromagnetic radiation during operation.

The emitter is preferably a surface emitter. This means that a large part of the electromagnetic radiation generated by the emitter during operation, for example at least 90% of the electromagnetic radiation generated during operation, is emitted via a planar main surface of the emitter. The planar main surface comprises, for example, an area of between 0.01 square millimeters and 5 square millimeters. The emitter is, for example, a light-emitting diode or a laser diode.

The emitter preferably comprises a high quantum efficiency. The quantum efficiency indicates the ratio between the radiant power emitted by the emitter and the electrical power absorbed by the emitter. For example, a quantum efficiency of the emitter is at least 70%.

For example, the emitter is operated with a constant electrical input voltage. Preferably, the electrical input voltage is between 1 Volt and 10 Volts, inclusive. Alternatively, the emitter can also be operated with a time-varying electrical input voltage. For example, a maximum frequency of the time-varying input voltage of the emitter is 10 Megahertz, wherein an amplitude is, for example, between 1 Volt and 10 Volts, inclusive.

During operation, the emitter preferably generates electromagnetic radiation in a wavelength range between ultraviolet and infrared light. For example, during operation, the emitter generates electromagnetic radiation with a wavelength between 220 nanometers and 1100 nanometers, inclusive. A spectral bandwidth of the electromagnetic radiation generated by the emitter during operation is preferably as narrow as possible. For example, a half-width of the spectrum of the electromagnetic radiation generated by the emitter is at most 50 nanometers.

According to a further embodiment, the optoelectronic component comprises a plurality of receivers forming a receiver array, wherein the receiver array converts electromagnetic radiation generated by the emitter during operation into an electrical output voltage.

The electrical output voltage of the receiver array is preferably larger than the electrical input voltage of the emitter. Alternatively, the electrical output voltage of the receiver array can also be equal to or less than the electrical input voltage of the emitter. The receiver array is preferably galvanically isolated from the emitter. Here and in the following, “galvanically isolated” means that an electrical circuit of the emitter is isolated from an electrical circuit of the receiver array. In particular, there is no direct contact and/or no electrically conductive connection between the electrical circuit of the emitter and the electrical circuit of the receiver array.

The features described below for one receiver preferably apply to all receivers of the receiver array. The receiver preferably comprises a radiation incoupling surface that is smaller than a radiation outcoupling surface of the emitter. The radiation incoupling surface of the receiver and the radiation outcoupling surface of the emitter are preferably planar surfaces. For example, the radiation incoupling surface of the receiver and the radiation outcoupling surface of the emitter are planar surfaces and arranged parallel to each other. For example, an area of the radiation incoupling surface of one receiver is between 100 square micrometers and 1 square millimeter, inclusive, while the radiation outcoupling surface of the emitter comprises an area between 0.01 square millimeters and 5 square millimeters, inclusive. Electromagnetic radiation generated by the emitter during operation that is incident on the radiation incoupling surface of the receiver is absorbed by the receiver and converted into an electrical output voltage.

According to an embodiment of the optoelectronic component, at least two receivers are arranged in a one-dimensional receiver array or in a two-dimensional receiver array. A receiver array preferably consists of a plurality of receivers arranged next to each other and forming a regular arrangement. Alternatively, the receivers of the receiver array can also be arranged irregularly, i.e. not periodically. Preferably, the radiation incoupling surfaces of all receivers of the receiver array are aligned in the same way. In other words, surface normals of the radiation outcoupling surfaces of all emitters run parallel to each other within a manufacturing tolerance.

The receiver is, for example, a photodiode or a phototransistor. The receiver preferably has a quantum efficiency of at least 70%. The quantum efficiency indicates a ratio of an electrical power emitted by the receiver to a power of the electromagnetic radiation absorbed by the receiver. In particular, a high quantum efficiency of the receiver is preferably achieved by configuring the receiver to absorb electromagnetic radiation with a narrow spectral bandwidth, which corresponds to the spectral bandwidth of the electromagnetic radiation generated by the emitter during operation.

For example, the receiver generates an electrical output voltage of between 0.5 Volts and 3 Volts during operation. By connecting the plurality of receivers in the receiver array in series, the electrical output voltage of the receiver array can be increased accordingly. For example, the electrical output voltage of the receiver array is between 100 Volts and 10000 Volts, inclusive.

According to a further embodiment of the optoelectronic component, radiation incoupling surfaces of the receivers are arranged on the radiation outcoupling surface of the emitter.

To increase an efficiency of the optoelectronic component, a large part of the electromagnetic radiation emitted from the radiation outcoupling surface is coupled into the radiation incoupling surfaces of the receivers. For example, at least 80% of the electromagnetic radiation generated by the emitter during operation is directed to radiation incoupling surfaces of the receivers. By arranging the radiation incoupling surfaces of the receivers directly on the radiation outcoupling surface of the emitter, the optoelectronic component comprises a particularly simple and compact design. In particular, low-voltage paths in the emitter and high-voltage paths in the receiver array are galvanically isolated.

According to a further embodiment of the optoelectronic component, a radiation-influencing element is arranged between the emitter and the receiver array, wherein the radiation-influencing element directs electromagnetic radiation generated by the emitter onto radiation incoupling surfaces of the receivers.

In particular, the radiation-influencing element is configured to increase a portion of the electromagnetic radiation generated by the emitter during operation that is absorbed in the radiation incoupling surfaces of the receivers. In particular, the radiation-influencing element reduces a portion of the electromagnetic radiation generated by the emitter during operation that is absorbed away from the radiation incoupling surfaces of the receivers and is thus not converted into an electrical output voltage. The radiation-influencing element thus increases the efficiency of the optoelectronic component.

According to a preferred embodiment, the optoelectronic component comprises the following features:
an emitter that is operated with an electrical input voltage and generates electromagnetic radiation during operation,
a plurality of receivers forming a receiver array, wherein the receiver array converts electromagnetic radiation generated by the emitter during operation into an electrical output voltage, wherein
radiation incoupling surfaces of the receivers are arranged on a radiation outcoupling surface of the emitter, and
a radiation-influencing element is arranged between the emitter and the receiver array, wherein the radiation-influencing element directs electromagnetic radiation generated by the emitter onto radiation incoupling surfaces of the receivers.

One idea of the present optoelectronic component is to provide an optical voltage converter having a structural form that is as compact as possible. Many applications, for example in acoustics, in microelectromechanical systems for beam control, as well as actuators and detectors, such as avalanche photodiodes, single photon avalanche photodiodes or photomultipliers, require a high voltage supply with relatively low power consumption. Such applications require operating voltages that are greater than 50 Volts, 100 Volts, 500 Volts, 1000 Volts, 2000 Volts or 10000 Volts, for example. The optical voltage converter should be as compact as possible, weigh as little as possible and consume as little energy as possible. Furthermore, the optical voltage converter should be as cost-effective as possible to produce. These properties are particularly important for mobile devices, such as augmented reality (AR) glasses, wearable in-ear headphones and automotive applications.

Furthermore, the connection of low-voltage paths and high-voltage paths should be prevented in high-voltage converters with a compact design. These should be galvanically isolated to ensure functional reliability and long-term stability under changing environmental conditions, such as temperature, humidity and dust.

In particular, by using highly efficient light-emitting diodes and structures that direct their light onto a large number of photodiodes, a high efficiency of the optoelectronic component described herein can be achieved. Low-voltage paths and high-voltage paths are galvanically isolated. In particular, the optoelectronic component described herein comprises no large coils and/or no large capacitors, which enables a lower weight and a more compact design. Generically, the optoelectronic components described herein can advantageously be manufactured in a wafer composite. By manufacturing the optoelectronic components in a wafer composite manufacturing costs can be reduced.

According to a further embodiment of the optoelectronic component, the emitter comprises a light-emitting diode.

The light-emitting diode comprises an epitaxial semiconductor layer sequence with an active layer for generating electromagnetic radiation. The semiconductor layer sequence preferably comprises an arsenide compound semiconductor material, a phosphide compound semiconductor material, or a nitride compound semiconductor material. Arsenide compound semiconductor materials preferably comprise AlₙGaₘIn₁₋ₙ₋ₘAs, where 0≤n≤1, 0≤m≤1 and n+m≤1. Phosphide compound semiconductors preferably comprise AlₙGaₘIn₁₋ₙ₋ₘP, where 0≤n≤1, 0≤m≤1 and n+m≤1. Nitride compound semiconductors preferably comprise AlₙGaₘIn₁₋ₙ₋ₘN, where 0≤n≤1, 0≤m≤1 and n+m≤1. Such compound semiconductor materials may also comprise, for example, one or more dopants and additional components.

The light-emitting diode is, for example, a flip chip or a thin-film chip. In particular, the flip chip comprises a growth substrate on which the epitaxial semiconductor layer sequence is grown. The growth substrate is transparent to electromagnetic radiation generated during operation, which is preferably coupled out via the growth substrate. In particular, electrical terminal contacts for contacting the active layer are arranged on a main surface of the epitaxial semiconductor layer sequence opposite the growth substrate. Furthermore, the electrical terminal contacts are preferably configured to reflect electromagnetic radiation generated during operation in the direction of the growth substrate.

In contrast to the flip chip, the thin-film chip does not comprise a growth substrate. Electromagnetic radiation generated during operation is coupled out via the radiation outcoupling surface of the thin-film chip. In particular, the radiation outcoupling surface is arranged parallel to a main extension plane of the epitaxial semiconductor layer sequence. For mechanical stabilization, a carrier is arranged on a main rear surface of the epitaxial semiconductor layer sequence opposite the radiation outcoupling surface. A reflective layer is preferably arranged between the main rear surface and the carrier, which deflects electromagnetic radiation generated during operation in the direction of the radiation outcoupling surface.

Electrical terminal contacts for energizing the active layer of the thin-film chip are usually arranged on a rear main surface of the carrier. If the radiation outcoupling surface is comparatively large, vias can be arranged in the epitaxial semiconductor layer sequence in order to achieve a uniform current supply.

According to a further embodiment, the optoelectronic component comprises a receiver array comprising an array of photodiodes electrically connected in series. The photodiodes preferably comprise a radiation incoupling surface that is smaller than the radiation outcoupling surface of the emitter. In particular, a particularly high electrical output voltage can be achieved by connecting the photodiodes in series.

According to a further embodiment of the optoelectronic component, electrical contact points of the receiver are arranged on a side of the receiver opposite the radiation incoupling surface. In the case that the receiver comprises a photodiode, the photodiode is in particular a flip-chip photodiode. In this case, the radiation incoupling surface of the receiver is free of electrical contact points for electrical contacting of the receiver.

According to a further embodiment of the optoelectronic component, the electrical contact points of the receiver are configured for an electrical interconnection of the plurality of receivers in the receiver array, wherein the radiation incoupling surface of the receiver is free of electrical contact elements for the electrical interconnection of the plurality of receivers. In particular, the radiation incoupling surface of the receiver is not covered by electrical contact elements for the electrical interconnection of the plurality of receivers. Thus, there are preferably no electrical contact elements between the radiation outcoupling surface of the emitter and the radiation incoupling surface of the receiver. This can increase the efficiency of the optoelectronic component.

According to a further embodiment of the optoelectronic component, the radiation-influencing element comprises a growth substrate on which the emitter is epitaxially grown. The growth substrate is transparent to electromagnetic radiation generated by the emitter during operation. The radiation incoupling surfaces of the receivers are applied to a main surface of the growth substrate that is facing away from the emitter.

For emitters comprising a nitride compound semiconductor material, the growth substrate comprises, for example, sapphire or silicon carbide or consists of sapphire or silicon carbide. For emitters comprising an arsenide compound semiconductor material, the growth substrate comprises, for example, GaAs or consists of GaAs. Electromagnetic radiation generated by the emitter during operation, which is coupled into the transparent growth substrate, is for example totally reflected at side surfaces of the growth substrate and thus deflected in the direction of the radiation incoupling surfaces of the receivers.

According to a further embodiment of the optoelectronic component, the receiver array is arranged on a wafer. In this case, the radiation incoupling surfaces of the receivers are arranged on a side of the receivers facing the wafer. The wafer is directly connected to the growth substrate of the receiver. In particular, the wafer and the growth substrate of the receiver are connected to each other without a joining layer and form a common interface.

In particular, the wafer is transparent to electromagnetic radiation generated by the emitter during operation. The receiver array can be epitaxially grown on the wafer, particularly in a wafer composite. This advantageously simplifies the manufacturing process of the optoelectronic component. In particular, the main surface of the growth substrate facing away from the emitter forms a common interface with a main surface of the wafer facing away from the receiver array, via which the growth substrate and the wafer are directly connected to each other without a joining layer.

The wafer on which the receiver array is arranged may comprise a different material or a different material system than the growth substrate on which the emitter is epitaxially grown. For example, the wafer and the growth substrate may comprise a different crystal structure. In particular, the wafer and the growth substrate do not form a continuous crystal.

Furthermore, the wafer can be connected to the growth substrate via an intermediate layer, for example. The intermediate layer comprises, for example, a glass, a metal and/or an adhesive.

According to a further embodiment of the optoelectronic component, the radiation-influencing element comprises trenches in the radiation outcoupling surface of the emitter, wherein the trenches are filled with a reflective material.

The trenches can, for example, be arranged directly in the semiconductor layer sequence of the emitter. Alternatively, the trenches can also be formed in a carrier, for example a growth substrate, to which the emitter is applied and via which electromagnetic radiation generated by the emitter during operation is coupled out. The trenches can comprise, for example, a triangular, rectangular, round or any other cross-section.

The reflective material comprises, for example, a metal or a dielectric material, such as titanium dioxide. Alternatively, the reflective material comprises reflective particles that are arranged in a matrix material, for example in a resin. Side surfaces of the trenches filled with the reflective material thus form reflective surfaces. In particular, these reflective surfaces are arranged in such a way that electromagnetic radiation generated by the emitter during operation is deflected in the direction of the radiation incoupling surfaces of the receivers.

According to a further embodiment of the optoelectronic component, the trenches are arranged over intermediate spaces between the receivers in the receiver array, such that electromagnetic radiation generated by the emitter during operation is not absorbed in the intermediate spaces.

The intermediate spaces between the receivers of the receiver array are filled with a dielectric material, for example. In particular, the dielectric material is configured to prevent a high-voltage breakdown between the receivers of the receiver array that are connected in series. Electromagnetic radiation generated by the emitter during operation that impinges the intermediate spaces is absorbed there, for example, and is thus lost. By arranging the trenches above the intermediate spaces of the receiver array, it is thus possible to prevent electromagnetic radiation generated by the emitter during operation from reaching the intermediate spaces.

According to a further embodiment of the optoelectronic component, the reflective material is electrically conductive and is configured for electrically contacting the emitter. In particular, the electrically conductive reflective material in the trenches can be used to electrically contact the active layer of a light-emitting diode.

According to a further embodiment of the optoelectronic component, an electrically insulating layer is arranged between the electrically conductive reflective material and the receiver array. The electrically insulating layer comprises, for example, a dielectric material and, in particular, prevents electrical short circuits in the receiver array.

According to a further embodiment of the optoelectronic component, the radiation-influencing element comprises an array of nano wires arranged on the radiation outcoupling surface of the emitter. In particular, a nano wire comprises a dielectric material, for example SiN. A nano wire comprises, for example, a circular, oval or polygonal cross-section.

According to one embodiment of the optoelectronic component, the nano wires are configured as waveguides for electromagnetic radiation generated by the emitter during operation.

By adapting a diameter of a nano wire as well as a distance between nano wires to the wavelength of the electromagnetic radiation generated by the emitter during operation, an incoupling efficiency into the array of nano wires can be optimized. In particular, an effective refractive index of the array of nano wires can be adjusted.

Preferably, the array of nanowires is configured such that each nanowire acts as a waveguide for electromagnetic radiation generated by the emitter during operation. Light that is coupled out of the array of nanowires thus comprises, for example, a point-like pattern that corresponds to the arrangement of the nanowires in the array of nanowires. In particular, the arrangement of the nanowires can be selected such that a large part, for example at least 90%, of the electromagnetic radiation coupled out of the array of nanowires impinges on radiation incoupling surfaces of the emitters. Here, the distance between the nano wires is selected, for example, such that no coupling of electromagnetic radiation occurs between the nano wires. In particular, the distance between the nano wires is larger than the wavelength of the electromagnetic radiation generated by the emitter during operation.

Due to the waveguiding properties of the array of nano wires, the optoelectronic component can comprise a particularly small receiver array. A minimal size of the receiver array is limited, for example, by a possible high-voltage breakdown. For this reason, filling the intermediate spaces between the receivers in the receiver array with an electrically insulating dielectric is particularly advantageous. A minimum distance between nano wires is, for example, between 10 nanometers and several 100 nanometers.

According to a further embodiment of the optoelectronic component, the nano wires are epitaxially grown on the radiation outcoupling surface of the emitter. Here, the emitter is preferably a thin-film chip, wherein the nano wires are grown on the main surface of the epitaxial semiconductor layer sequence of the thin-film chip that is configured for coupling out electromagnetic radiation generated during operation.

According to a further embodiment of the optoelectronic component, the array of nano wires and the receiver array are mechanically and/or optically connected to each other, wherein one nano wire is connected to the radiation incoupling surface of one of the receivers, respectively.

Preferably, a cross-sectional area of the nano wire corresponds to the radiation incoupling surface of the receiver. The nano wire is bonded to the radiation incoupling surface of the receiver, for example. Accordingly, a particularly efficient coupling of the emitter to the receiver array is achieved.

According to a further embodiment of the optoelectronic component, the radiation-influencing element comprises a photonic crystal that is arranged on the radiation outcoupling surface of the emitter.

Here, a photonic crystal is a periodic structure that is transparent to electromagnetic radiation generated by the emitter during operation, wherein a refractive index varies periodically within the photonic crystal. In particular, the photonic crystal is configured to shape the far field of the electromagnetic radiation generated by the emitter during operation. For example, the photonic crystal is configured as a diffraction grating for electromagnetic radiation generated by the emitter during operation. The photonic crystal comprises, for example, structured semiconductors, structured glasses or structured polymers.

According to a further embodiment of the optoelectronic component, the photonic crystal comprises a plurality of regions, wherein the regions are configured to deflect electromagnetic radiation generated by the emitter during operation into predetermined solid angle regions in which radiation incoupling surfaces of the receivers are located.

In particular, a region of the photonic crystal focuses electromagnetic radiation from the emitter onto the radiation incoupling surface of an associated receiver. As a result, a beam shape of the electromagnetic radiation generated by the emitter during operation can be optimally adapted to the receiver array. In particular, the receiver array can be larger than the radiation outcoupling surface of the emitter. For high-voltage applications, the receiver array can thus comprise larger intermediate spaces in order to avoid high-voltage breakdowns.

According to a further embodiment of the optoelectronic component, the photonic crystal comprises an array of nano wires.

By appropriately selecting the diameter of a nano wire, as well as the spacing between nano wires and their arrangement in the array of nano wires, a photonic crystal with predetermined properties can be achieved, in particular. At small distances between the nanowires, in particular at distances smaller than the wavelength of the electromagnetic radiation generated by the emitter during operation, coupling of electromagnetic radiation between the nanowires can take place. This coupling can be used to shape the electromagnetic far field coupled out of the array of nano wires. In particular, the receiver array is arranged in the electromagnetic far field of the array of nano wires. The far field is shaped, for example, such that electromagnetic radiation impinges, in particular, on the radiation incoupling surfaces of the receivers.

According to a further embodiment of the optoelectronic component, the radiation-influencing element comprises a microlens array, wherein a microlens is arranged on the radiation incoupling surface of a receiver, which focuses the electromagnetic radiation generated by the emitter during operation onto the radiation incoupling surface of the receiver.

According to a further embodiment of the optoelectronic component, the radiation-influencing element comprises reflectors arranged between the receivers. Preferably, the reflectors comprise a dielectric material to avoid high voltage breakdown between the receivers. Furthermore, the reflectors comprise a reflective surface which is designed to deflect electromagnetic radiation generated by the emitter during operation onto the radiation incoupling surfaces of the receivers.

The reflectors are created, for example, during a manufacturing process of the receiver array in the wafer composite. For example, a dielectric is applied and formed. A reflective metallic layer is then applied to parts of the reflectors, for example. Alternatively, a preformed frame can be fixed in the intermediate spaces between the receivers of the receiver array, whereby the frame comprises, for example, an embossed polymer, in particular polydimethylsiloxane, or a metal. As another alternative, for example, a silicone and a metal can be applied to the receiver array by means of spray coating and a stencil. The reflectors can also be configured as a moisture barrier, in particular to increase the reliability of the electrical contact elements.

According to a further embodiment of the optoelectronic component, intermediate spaces between the receivers of the receiver array are filled with a dielectric material. In particular, the dielectric material is configured to avoid high-voltage breakdowns between a plurality of receivers that are connected in series.

Further advantageous embodiments and further developments of the optoelectronic component follow from the exemplary embodiments described below in connection with the figures.

### BRIEF DESCRIPTION OF THE DRAWINGS

FIG. 1 shows a schematic sectional view of an optoelectronic component according to an exemplary embodiment.

FIGS. 2A and 2B show schematic representations of an optoelectronic component according to a further exemplary embodiment.

FIGS. 3A and 3B show schematic representations of an optoelectronic component according to a further exemplary embodiment.

FIG. 4 shows a schematic sectional view of an optoelectronic component according to a further exemplary embodiment.

FIGS. 5A and 5B show schematic representations of an optoelectronic component according to a further exemplary embodiment.

FIG. 6 shows a schematic sectional view of an optoelectronic component according to a further exemplary embodiment.

FIG. 7 shows a schematic sectional view of a receiver array according to an exemplary embodiment.

### DETAILED DESCRIPTION

Elements that are identical, similar or have the same effect are marked with the same reference signs in the figures. The figures and the proportions of the elements shown in the figures are not to be regarded as true to scale. Rather, individual elements, in particular layer thicknesses, may be shown exaggeratedly large for better visualization and/or understanding.

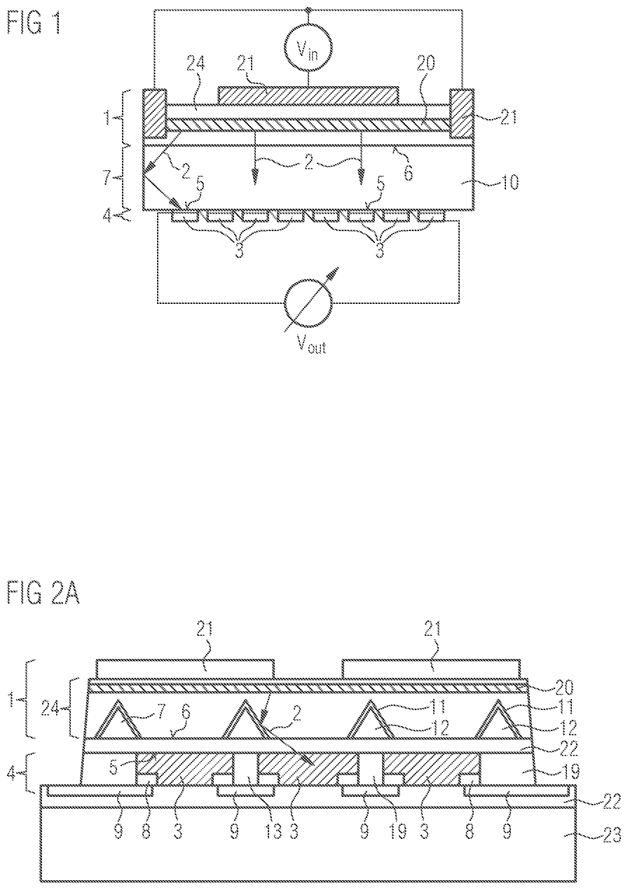

The exemplary embodiment in FIG. 1 shows a schematic sectional view of an optoelectronic component comprising an emitter 1, a receiver array 4 and a radiation-influencing element 7. In particular, the optoelectronic component is configured to convert an electrical input voltage Vᵢₙ into an output voltage Vₒᵤₜ. The electrical output voltage Vₒᵤₜ is preferably higher than the electrical input voltage Vᵢₙ but can also be equal to or lower than the electrical input voltage Vᵢₙ.

The emitter 1 is a light emitting diode comprising an epitaxial semiconductor layer sequence 24 with an active layer 20 for generating electromagnetic radiation 2. The light emitting diode preferably comprises a nitride compound semiconductor material or an arsenide compound semiconductor material. Furthermore, the light-emitting diode comprises terminal contacts 21 for electrically contacting the active layer 20.

The epitaxial semiconductor layer sequence 24 of the light emitting diode is epitaxially grown on a growth substrate 10. The growth substrate 10 is transparent for the electromagnetic radiation 2 generated by the active layer 20 during operation. A large part of the electromagnetic radiation 2 generated during operation, preferably more than 90%, is coupled into the growth substrate 10 via a radiation outcoupling surface 6 of the light-emitting diode. For this purpose, the light-emitting diode comprises an electrical terminal contact 21, which comprises a reflective layer on a main surface of the epitaxial semiconductor layer sequence 24 facing away from the growth substrate 10. The reflective layer of the electrical terminal contact 21 preferably completely covers the main surface of the epitaxial semiconductor layer sequence 24. In particular, the terminal contact 21 is configured to deflect electromagnetic radiation 2 generated by the active layer 20 during operation in the direction of the radiation outcoupling surface 6.

The receiver array 4 is applied to a main surface of the growth substrate 10 that is opposite the light-emitting diode. This main surface is preferably polished. In particular, the receiver array 4 comprises a plurality of receivers 3, which are formed as photodiodes. The photodiodes are arranged in the form of a regular two-dimensional array and are electrically connected in series. In particular, radiation incoupling surfaces 5 of the photodiodes face the growth substrate 10. Here, the photodiodes are detached from a wafer on which the photodiodes have been grown. Alternatively, the photodiodes can also be arranged on a wafer that is connected to the growth substrate 10 via a common interface without a joining layer.

The photodiodes are preferably based on the same semiconductor compound material system as the epitaxial semiconductor layer sequence 24 of the light-emitting diode. In particular, the photodiodes are configured to absorb the electromagnetic radiation 2 generated by the emitter during operation.

The growth substrate 10 forms a radiation-influencing element 7, which is configured to direct electromagnetic radiation 2 generated during operation from the radiation outcoupling surface 6 of the emitter 1 to the radiation incoupling surfaces 5 of the receivers 3. For example, electromagnetic radiation 2 generated during operation is totally reflected at side surfaces of the growth substrate 10 and deflected in the direction of the radiation incoupling surfaces 5 of the receivers 3. For this purpose, the side surfaces of the growth substrate 10 may comprise an additional reflective coating. In particular, the receiver array 4 is homogeneously illuminated and there is no air gap between the radiation outcoupling surface 6 of the emitter and the radiation incoupling surfaces 5 of the receivers 3. In particular, the optoelectronic component described here can be manufactured easily and inexpensively, with an efficiency of the optoelectronic component being determined by a fill factor of the radiation incoupling surfaces 5 of the receivers 3 of the receiver array 4.

FIG. 2A shows a schematic sectional view of an optoelectronic component according to a further exemplary embodiment. The optoelectronic component comprises an emitter 1 in the form of a light-emitting diode, a receiver array 4 with a plurality of receivers 3 connected in series, and a radiation-influencing element 7. The receivers 3 are designed as photodiodes. In particular, the light-emitting diode is a thin-film chip comprising, for example, a particularly efficient UX:3 architecture. In particular, the thin-film chip comprises electrical terminal contacts 21 which are arranged on a side of the epitaxial semiconductor layer sequence 24 opposite to the radiation outcoupling surface 6. In contrast to the exemplary embodiment in FIG. 1, the optoelectronic component in FIG. 2A does not comprise a growth substrate 10 of the emitter 1.

The radiation-influencing element 7 comprises trenches 11 in the radiation outcoupling surface 6 of the light-emitting diode, which are filled with a reflective material 12. Electromagnetic radiation 2 generated by the active layer 20 during operation is directed from reflective side surfaces of the trenches 11 onto radiation incoupling surfaces 5 of the receivers 3. In particular, the trenches 11 are arranged over intermediate spaces 13 between the receivers 3 of the receiver array 4. The trenches 11 filled with the reflective material 12 thus prevent electromagnetic radiation 2 emitted during operation from impinging intermediate spaces 13 between the photodiodes in the receiver array 4 and being absorbed there.

In particular, the photodiodes of the receiver array 4 are flip-chip photodiodes comprising electrical contact points 8 on a main surface of the photodiodes opposite the radiation incoupling surface 5. The radiation incoupling surfaces 5 are thus free of electrical contact elements 9 for a series connection of the plurality of photodiodes in the receiver array 4.

For example, the receiver array 4 is attached to the radiation outcoupling surface 6 of the light-emitting diode with a transparent adhesive 22. The transparent adhesive 22 is preferably electrically insulating. As a result, a circuit of the emitter 1 is electrically isolated from a circuit of the receiver array 4.

The optoelectronic component is furthermore attached to a carrier 23, for example with an adhesive 22, which is configured for heat dissipation. The optoelectronic component described here comprises a compact design and a high efficiency, which is in particular independent of a filling factor of the receiver array 4.

FIG. 2B shows a schematic representation of the optoelectronic component of FIG. 2A as seen from the carrier 23, with the receivers 3 of the receiver array 4 forming a regular two-dimensional arrangement. The receivers 3 are connected in series via electrical contact elements 9. The electrical contact elements 9 are arranged on a main surface of the receivers 3 opposite to the radiation incoupling surface 5.

Intermediate spaces 13 between the receivers 3 of the receiver array 4 are filled with a dielectric material 19. In particular, the dielectric material 19 serves to prevent high-voltage breakdowns of the large number of receivers 3 connected in series. For better visualization, only six receivers 3 in the receiver array 4 are shown here. However, the receiver array may comprise a larger number of receivers 3, for example 100, 1000 or 10000 receivers 3.

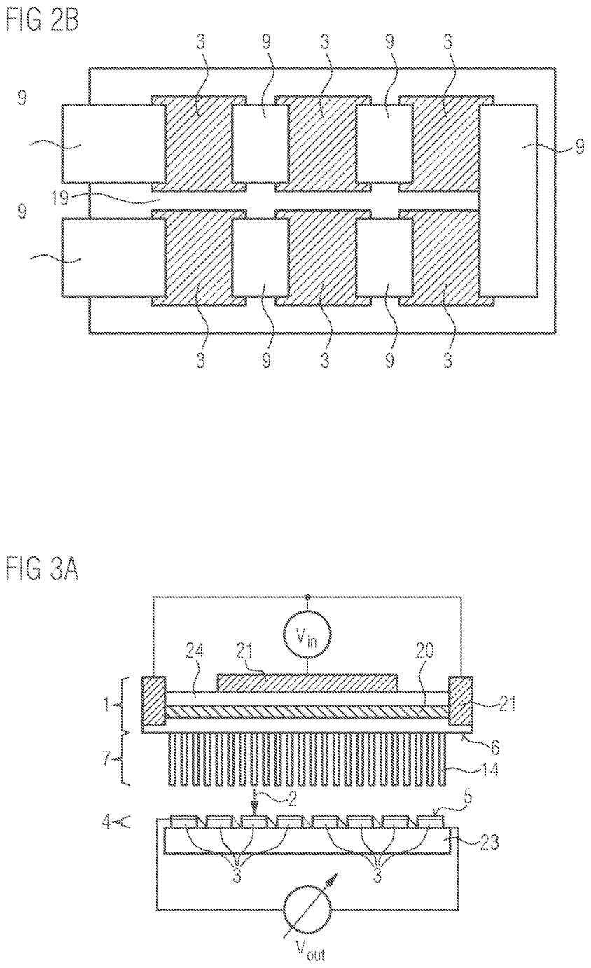

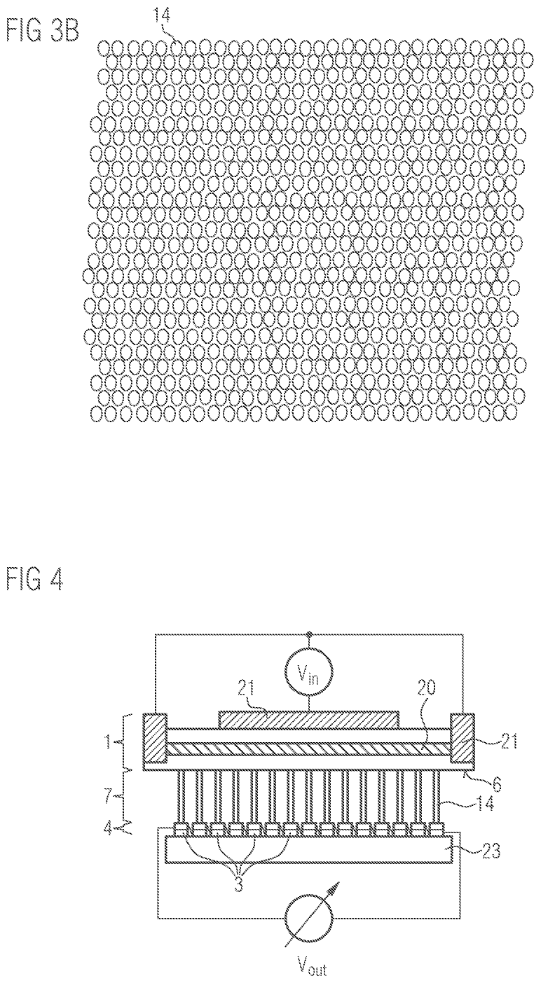

FIG. 3A shows a schematic sectional view of a further exemplary embodiment of the optoelectronic component. In contrast to the exemplary embodiment in FIG. 1, here no growth substrate 10 is arranged between the emitter 1 and the receiver array 4. Here, the radiation-influencing element 7 is formed by an array of nano wires 14. In particular, the nano wires 14 are configured as waveguides for electromagnetic radiation 2 generated during operation and guide electromagnetic radiation 2 from the radiation outcoupling surface 6 of the light-emitting diode to the radiation incoupling surfaces 5 of the photodiodes of the receiver array.

FIG. 3B shows a schematic cross-section through the array of nano wires 14 of FIG. 3A. The nano wires 14 comprise a circular cross-section, wherein a diameter of a nano wire corresponds, for example, to the wavelength of the electromagnetic radiation 2 emitted during operation divided by a refractive index of the nano wire 14. A distance between the nano wires 14 can be between 10 nanometers and several 100 nanometers, inclusive.

The nano wires 14 comprise a dielectric material, for example silicon nitride, and are deposited on the radiation outcoupling surface 6 of the emitter 1. For example, the array of nano wires 14 may be epitaxially grown on the radiation outcoupling surface 6 of the emitter 1. In this case, the nano wires 14 preferably comprise a material from the same material family as the epitaxial semiconductor layer sequence 24 of the emitter 1.

Alternatively, the array of nano wires 14 can be fabricated by a process in which a layer of a dielectric material is deposited on the radiation outcoupling surface 6 of the emitter 1. Subsequently, the array of nano wires 14 may be fabricated from the dielectric layer by a lithographic process. For this purpose, for example, a photoresist mask is applied to the dielectric layer in the form of the array of nano wires 14. The dielectric layer is then removed in regions not covered by the photoresist mask by an etching process, for example.

FIG. 4 shows a schematic sectional view of an optoelectronic component according to a further embodiment. Here, in contrast to the optoelectronic component in FIG. 3A, the nano wires 14 are connected directly to radiation incoupling surfaces 5 of the photodiodes of the receiver array 4. In particular, one end of each nano wire 14 is connected to the radiation incoupling surface 5 of one receiver 3. Here, the nano wire 14 comprises a cross-sectional area that corresponds to the radiation incoupling surface 5 of the receiver 1. One end of a nano wire 14 is connected to the radiation incoupling surface 5 of a receiver, respectively. This design is particularly suitable for optical voltage converters with a very high electrical output voltage Vₒᵤₜ, which comprise a large number of receivers 3 in the receiver array 4.

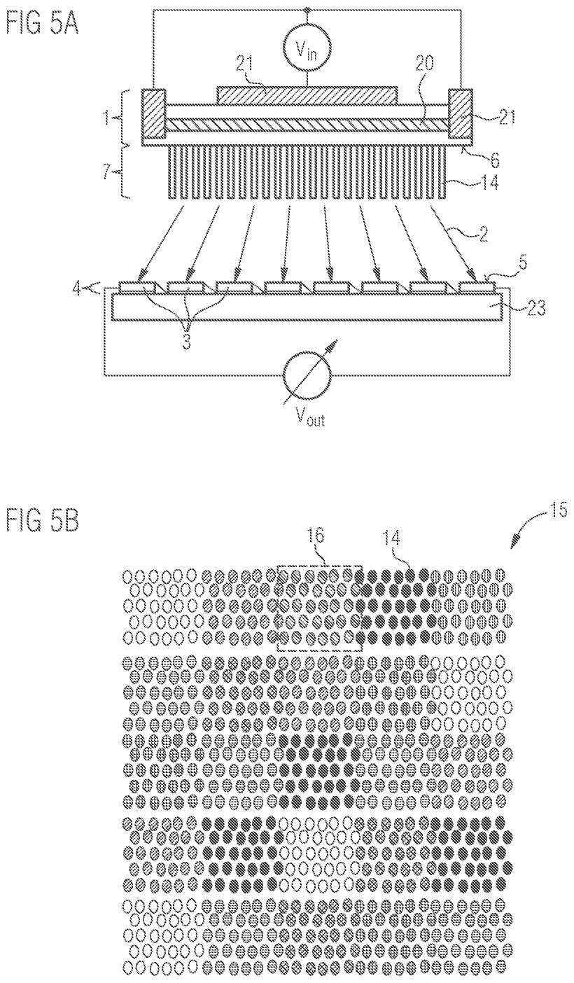

FIG. 5A shows a schematic sectional view of an optoelectronic component according to a further exemplary embodiment. As in the optoelectronic component of the exemplary embodiment of FIG. 3A, the radiation-influencing element 7 is formed here by an array of nano wires 14. In contrast to FIG. 3A, however, here the nano wires 14 do not form waveguides, but are formed as a photonic crystal 15. In particular, the photonic crystal 15 comprises several regions 16, each of which deflects the electromagnetic radiation 2 generated during operation into a solid angle element in which the radiation incoupling surface 5 of a receiver 3 is located.

FIG. 5B shows a schematic cross-section through the array of nano wires 14 of FIG. 5A. The array of nano wires 14 comprises a plurality of regions 16. The number of different regions 16 corresponds to the number of receivers 3 in the receiver array 4. A region 16 is configured to focus electromagnetic radiation 2 generated during operation onto the radiation incoupling surface 5 of an associated receiver 3.

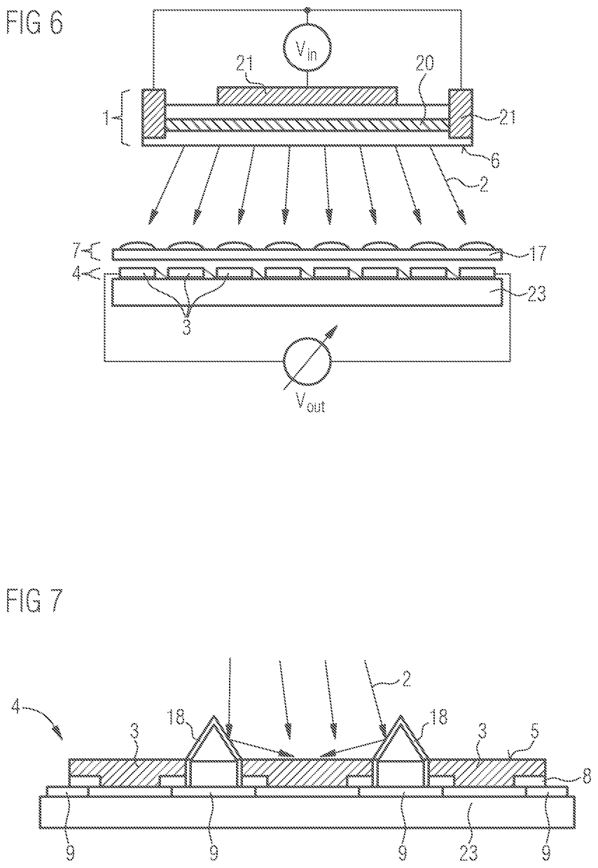

FIG. 6 shows a schematic sectional view of an optoelectronic component according to a further embodiment. In contrast to the optoelectronic component of FIG. 5A, the radiation-influencing element 7 is formed here as an array of microlenses 17. In particular, a microlens is located above each receiver 3 of the receiver array 4, which focuses the electromagnetic radiation 2 generated by the emitter during operation onto the radiation incoupling surface 5 of the receiver 3.

FIG. 7 shows a schematic sectional view of a receiver array 4 according to an exemplary embodiment. In contrast to the receiver array 4 of FIG. 2A, radiation-influencing elements 7 are arranged here between the receivers 3 of the receiver array 4. In particular, the radiation-influencing elements 7 are formed as reflectors 18, which deflect electromagnetic radiation 2 onto radiation incoupling surfaces 5 of the receivers 3. In particular, the reflectors comprise a dielectric material with a reflective coating and are applied as prefabricated elements in intermediate spaces 13 between the receivers 3.

This invention is not limited to the description based on the exemplary embodiments. Rather, the invention includes any new feature as well as any combination of features, which includes in particular any combination of features in the patent claims, even if this feature or combination itself is not explicitly stated in the patent claims or exemplary embodiments.

1. An optoelectronic component, comprising:
an emitter that is operated with an electrical input voltage and generates electromagnetic radiation during operation, and
a plurality of receivers forming a receiver array, wherein the receiver array converts electromagnetic radiation generated by the emitter during operation into an electrical output voltage, wherein
radiation incoupling surfaces of the receivers are arranged on a radiation outcoupling surface of the emitter,
a radiation-influencing element is arranged between the emitter and the receiver array, wherein the radiation-influencing element directs electromagnetic radiation generated by the emitter onto radiation incoupling surfaces of the receivers,
the radiation-influencing element comprises a growth substrate on which the emitter is epitaxially grown, and
the receiver array is arranged on a wafer that is directly connected to the growth substrate.

2. The optoelectronic component according to claim 1, wherein the emitter comprises a light-emitting diode and the receiver array comprises an array of photodiodes electrically connected in series.

3. The optoelectronic component according to claim 1, wherein
electrical contact points of the receiver are arranged on a side of the receiver opposite to the radiation incoupling surface, and
the electrical contact points of the receiver are configured for an electrical interconnection of the plurality of receivers in the receiver array, wherein the radiation incoupling surface of the receiver is free of electrical contact elements for the electrical interconnection of the plurality of receivers.

4. The optoelectronic component according to claim 1, wherein
the growth substrate is transparent for electromagnetic radiation generated by the emitter during operation, and
the radiation incoupling surfaces of the receivers are applied to a main surface of the growth substrate that is facing away from the emitter.

5. The optoelectronic component according to claim 4, wherein
the radiation incoupling surfaces of the receivers are arranged on a side of the receivers facing the wafer.

6. The optoelectronic component according to claim 1, wherein
the radiation-influencing element comprises trenches in the radiation outcoupling surface of the emitter, and
the trenches are filled with a reflective material.

7. The optoelectronic component according to claim 6, wherein the trenches are arranged over intermediate spaces between the receivers in the receiver array, such that electromagnetic radiation generated by the emitter during operation is not absorbed in the intermediate spaces.

8. The optoelectronic component according to claim 6, wherein
the reflective material is electrically conductive and is configured for electrically contacting the emitter, and
an electrically insulating layer is arranged between the reflective material and the receiver array.

9. The optoelectronic component according to claim 1, wherein
the radiation-influencing element comprises an array of nano wires arranged on the radiation outcoupling surface of the emitter, and
the nano wires are configured as waveguides for electromagnetic radiation generated by the emitter during operation.

10. The optoelectronic component according to claim 9, wherein the nano wires are epitaxially grown on the radiation outcoupling surface of the emitter.

11. The optoelectronic component according to claim 9, wherein
the array of nano wires and the receiver array are mechanically and/or optically connected to each other, and
one nano wire is connected to the radiation incoupling surface of one of the receivers, respectively.

12. The optoelectronic component according to claim 1, wherein the radiation-influencing element comprises a photonic crystal that is arranged on the radiation outcoupling surface of the emitter.

13. The optoelectronic component according to claim 12, wherein the photonic crystal comprises a plurality of regions, wherein the regions are configured to deflect electromagnetic radiation generated by the emitter during operation into predetermined solid angle regions in which radiation incoupling surfaces of the receivers are located.

14. The optoelectronic component according to claim 12, wherein the photonic crystal comprises an array of nano wires.

15. The optoelectronic component according to claim 1, wherein
the radiation-influencing element comprises a microlens array, and
a microlens is arranged on the radiation incoupling surface of a receiver, which focuses the electromagnetic radiation generated by the emitter during operation onto the radiation incoupling surface of the receiver.

16. The optoelectronic component according to claim 1, wherein the radiation-influencing element comprises reflectors arranged between the receivers.

17. The optoelectronic component according to claim 1, wherein intermediate spaces between the receivers of the receiver array are filled with a dielectric material.

18. An optoelectronic component, comprising:
an emitter that is operated with an electrical input voltage and generates electromagnetic radiation during operation; and
a plurality of receivers forming a receiver array, wherein the receiver array converts electromagnetic radiation generated by the emitter during operation into an electrical output voltage, wherein
radiation incoupling surfaces of the receivers are arranged on a radiation outcoupling surface of the emitter,
a radiation-influencing element is arranged between the emitter and the receiver array, wherein the radiation-influencing element directs electromagnetic radiation generated by the emitter onto radiation incoupling surfaces of the receivers,
the radiation-influencing element comprises an array of nano wires arranged on the radiation outcoupling surface of the emitter, and
the nano wires are configured as waveguides for electromagnetic radiation generated by the emitter during operation.

19. An optoelectronic component, comprising:
an emitter that is operated with an electrical input voltage and generates electromagnetic radiation during operation; and
a plurality of receivers forming a receiver array, wherein the receiver array converts electromagnetic radiation generated by the emitter during operation into an electrical output voltage, wherein
radiation incoupling surfaces of the receivers are arranged on a radiation outcoupling surface of the emitter,
a radiation-influencing element is arranged between the emitter and the receiver array, wherein the radiation-influencing element directs electromagnetic radiation generated by the emitter onto radiation incoupling surfaces of the receivers,
the radiation-influencing element comprises a photonic crystal that is arranged on the radiation outcoupling surface of the emitter, and
the photonic crystal comprises a plurality of regions, wherein the regions are configured to deflect electromagnetic radiation generated by the emitter during operation into predetermined solid angle regions in which radiation incoupling surfaces of the receivers are located.
